(19) United States
(12) Patent Application Publication
(10) Pub. No.: US 2026/0047219 A1
(43) Pub. Date: Feb. 12, 2026

(54) SENSOR PACKAGE STRUCTURE

(71) Applicant: TONG HSING ELECTRONIC INDUSTRIES, LTD., Taoyuan City (TW)

(72) Inventors: Chi-Jung Huang, Taoyuan City (TW); YU-WEN LI, Taoyuan City (TW); LI-CHUN HUNG, Taoyuan City (TW)

(21) Appl. No.: 18/945,544

(22) Filed: Nov. 13, 2024

(30) Foreign Application Priority Data
Aug. 7, 2024 (TW) 113129475

(51) Int. Cl. H01L 27/146; H01L 23/00

(52) U.S. Cl. CPC H10F 39/804; H10F 39/809; H10F 39/811; H01L 24/48; H01L 2224/48229

(57) ABSTRACT

A sensor package structure includes a substrate, a sensor chip disposed on a top side of the substrate, a plurality of metal wires connecting the substrate and the sensor chip, an embedded module embedded in a bottom side of the substrate, and a light-permeable cover that is assembled to the top side of the substrate. The substrate has an accommodating slot recessed in the bottom side of the substrate, and the embedded module is disposed in the accommodating slot and includes a processor, an underfill layer, and an inner encapsulant. The processor is connected to the substrate through solders, and the processor is electrically coupled to the sensor chip through the substrate and the metal wires. The solders are embedded in the underfill layer, the accommodating slot is fully filled with the inner encapsulant, and the processor and the underfill layer are embedded in the inner encapsulant.

### CROSS-REFERENCE TO RELATED PATENT APPLICATION

This application claims the benefit of priority to Taiwan Patent Application No. 113129475, filed on Aug. 7, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package structure.

### BACKGROUND OF THE DISCLOSURE

When a conventional sensor package structure is in operation, signal transmission paths formed in the conventional sensor package structure are too long, which is not conducive to increasing overall performance. Moreover, the size of the conventional sensor package structure is too large, which is not conducive to further development of sensor package structures.

### SUMMARY OF THE DISCLOSURE

In response to the above-referenced technical inadequacies, the present disclosure provides a sensor package structure for effectively improving on the issues associated with conventional sensor package structures.

In order to solve the above-mentioned problems, one of the technical aspects adopted by the present disclosure is to provide a sensor package structure, which includes a substrate, a sensor chip, a plurality of metal wires, an embedded module, a ring-shaped frame, a ring-shaped supporting layer, and a light-permeable sheet. The substrate includes an upper surface and a lower surface. The upper surface has a chip-bonding region and a carrying region that surrounds the chip-bonding region. The lower surface is opposite to the upper surface. The substrate has an accommodating slot that is recessed from the lower surface toward the chip-bonding region. The substrate includes a plurality of first bonding pads arranged on the carrying region, a plurality of second bonding pads arranged on a bottom of the accommodating slot, and a fan-out circuit that extends from the second bonding pads to the first bonding pads. The sensor chip is disposed on the chip-bonding region. A top surface of the sensor chip has a sensing region and a plurality of connection pads that are arranged outside of the sensing region. Each of the metal wires has a first end portion and a second end portion. The first end portions of the metal wires are respectively connected to the first bonding pads, and the second end portions of the metal wires are respectively connected to the connection pads. The embedded module is arranged in the accommodating slot and includes a processor, an underfill layer, and an inner encapsulant. The processor is disposed in the accommodating slot and does not protrude from the lower surface. The processor is connected to the second bonding pads through solders, and the processor is electrically coupled to the sensor chip through the substrate and the metal wires. The underfill layer is arranged between the processor and the bottom of the accommodating slot. The solders and the second bonding pads are embedded in the underfill layer. The inner encapsulant is filled fully in the accommodating slot. The processor and the underfill layer are embedded in the inner encapsulant, and an outer side of the inner encapsulant is coplanar with the lower surface of the substrate. The ring-shaped frame is formed on the carrying region of the upper surface and surrounds the sensor chip and the metal wires. The ring-shaped supporting layer is formed on the ring-shaped frame. The light-permeable sheet is fixed to the ring-shaped supporting layer to enable the light-permeable sheet, the ring-shaped supporting layer, the ring-shaped frame, and the upper surface of the substrate to jointly define an enclosed space. The sensor chip and the metal wires are located in the enclosed space.

In order to solve the above-mentioned problems, another one of the technical aspects adopted by the present disclosure is to provide a sensor package structure, which includes a substrate, a sensor chip, a plurality of metal wires, an embedded module, a ring-shaped supporting layer, a light-permeable sheet, and an outer encapsulant. The substrate includes an upper surface and a lower surface. The upper surface has a chip-bonding region and a carrying region that surrounds the chip-bonding region. The lower surface is opposite to the upper surface. The substrate has an accommodating slot that is recessed from the lower surface toward the chip-bonding region. The substrate includes a plurality of first bonding pads arranged on the carrying region, a plurality of second bonding pads arranged on a bottom of the accommodating slot, and a fan-out circuit that extends from the second bonding pads to the first bonding pads. The sensor chip is disposed on the chip-bonding region. A top surface of the sensor chip has a sensing region and a plurality of connection pads that are arranged outside of the sensing region. Each of the metal wires has a first end portion and a second end portion. The first end portions of the metal wires are respectively connected to the first bonding pads, and the second end portions of the metal wires are respectively connected to the connection pads. The embedded module is arranged in the accommodating slot and includes a processor, an underfill layer, and an inner encapsulant. The processor is disposed in the accommodating slot and does not protrude from the lower surface. The processor is connected to the second bonding pads through solders, and the processor is electrically coupled to the sensor chip through the substrate and the metal wires. The underfill layer is arranged between the processor and the bottom of the accommodating slot. The solders and the second bonding pads are embedded in the underfill layer. The inner encapsulant is filled fully in the accommodating slot. The processor and the underfill layer are embedded in the inner encapsulant, and an outer side of the inner encapsulant is coplanar with the lower surface of the substrate. The ring-shaped supporting layer is formed on the top surface of the sensor and surrounds the sensing region. The light-permeable sheet is fixed to the ring-shaped supporting layer to enable the light-permeable sheet, the ring-shaped supporting layer, and the top surface of the sensor to jointly define an enclosed space. The sensing region is located in the enclosed space. The outer encapsulant is formed on the carrying region of the substrate. The first bonding pads, at least part of each of the metal wires, the sensor chip, the ring-shaped supporting layer, and the light-permeable sheet are embedded in the outer encapsulant. An outer surface of the light-permeable sheet is at least partially exposed from the outer encapsulant.

In order to solve the above-mentioned problems, yet another one of the technical aspects adopted by the present disclosure is to provide a sensor package structure, which includes a substrate, a sensor chip, a plurality of metal wires, an embedded module, and a light-permeable cover. The substrate includes an upper surface and a lower surface. The upper surface has a chip-bonding region and a carrying region that surrounds the chip-bonding region. The lower surface is opposite to the upper surface. The substrate has an accommodating slot that is recessed from the lower surface toward the chip-bonding region. The substrate includes a plurality of first bonding pads arranged on the carrying region, a plurality of second bonding pads arranged on a bottom of the accommodating slot, and a fan-out circuit that extends from the second bonding pads to the first bonding pads. The sensor chip is disposed on the chip-bonding region. A top surface of the sensor chip has a sensing region and a plurality of connection pads that are arranged outside of the sensing region. Each of the metal wires has a first end portion and a second end portion. The first end portions of the metal wires are respectively connected to the first bonding pads, and the second end portions of the metal wires are respectively connected to the connection pads. The embedded module is arranged in the accommodating slot and includes a processor, an underfill layer, and an inner encapsulant. The processor is disposed in the accommodating slot and does not protrude from the lower surface. The processor is connected to the second bonding pads through solders, and the processor is electrically coupled to the sensor chip through the substrate and the metal wires. The underfill layer is arranged between the processor and the bottom of the accommodating slot. The solders and the second bonding pads are embedded in the underfill layer. The inner encapsulant is filled fully in the accommodating slot. The processor and the underfill layer are embedded in the inner encapsulant, and an outer side of the inner encapsulant is coplanar with the lower surface of the substrate. The light-permeable cover is assembled to the carrying region. The light-permeable cover and the upper surface of the substrate jointly define an enclosed space, and the sensor chip and the metal wires are located in the enclosed space.

Therefore, the sensor package structure of the present disclosure is provided with the structural cooperation of the substrate and the embedded module, so that signal transmission paths between the sensor chip and the processor can be significantly shortened to increase overall performance, and the sensor package structure can be effectively miniaturized to facilitate future development and application.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a sensor package structure according to a first embodiment of the present disclosure;

FIG. 2 is a schematic top view of FIG. 1 when a ring-shaped supporting layer, a light-permeable sheet, and a solidified liquid compound are omitted;

FIG. 3 is a schematic cross-sectional view taken along line III-III of FIG. 1;

FIG. 4 is a schematic cross-sectional view showing the sensor package structure of FIG. 3 in another configuration;

FIG. 5 is a schematic perspective view of the sensor package structure according to a second embodiment of the present disclosure;

FIG. 6 is a schematic cross-sectional view taken along line VI-VI of FIG. 5;

FIG. 7 is a schematic cross-sectional view showing the sensor package structure of FIG. 6 in another configuration;

FIG. 8 is a schematic perspective view of the sensor package structure according to a third embodiment of the present disclosure;

FIG. 9 is a schematic exploded view of FIG. 8; and

FIG. 10 is a schematic cross-sectional view taken along line X-X of FIG. 8.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

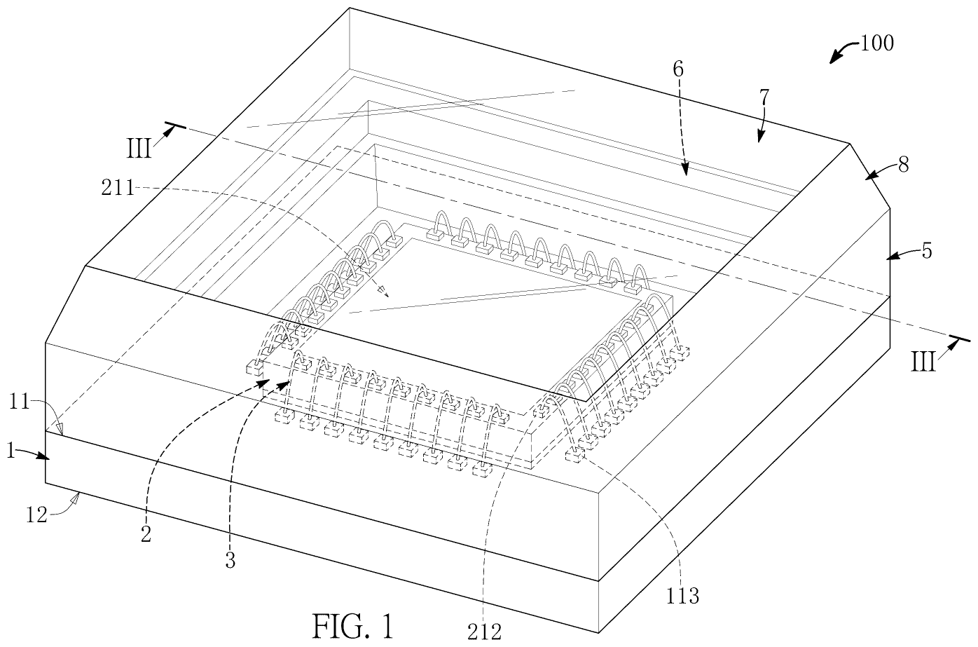

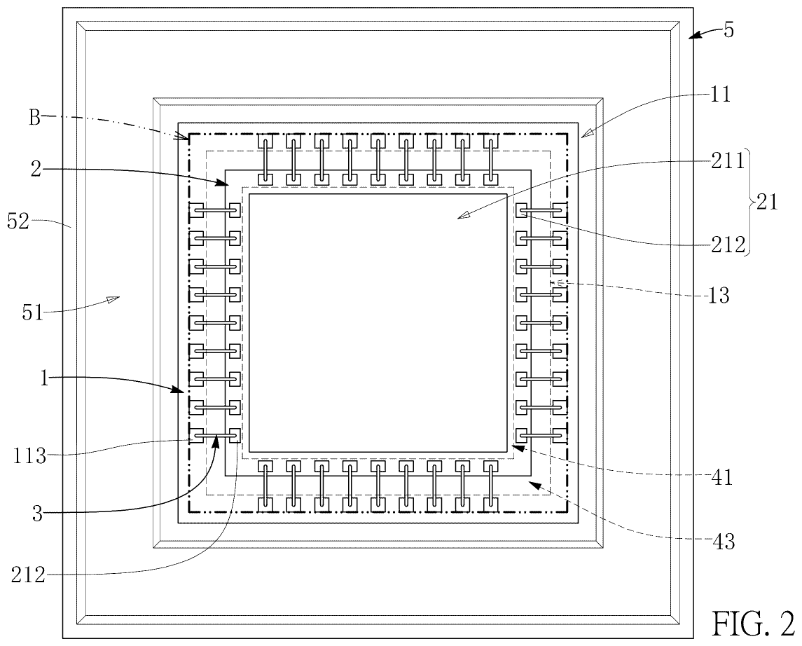

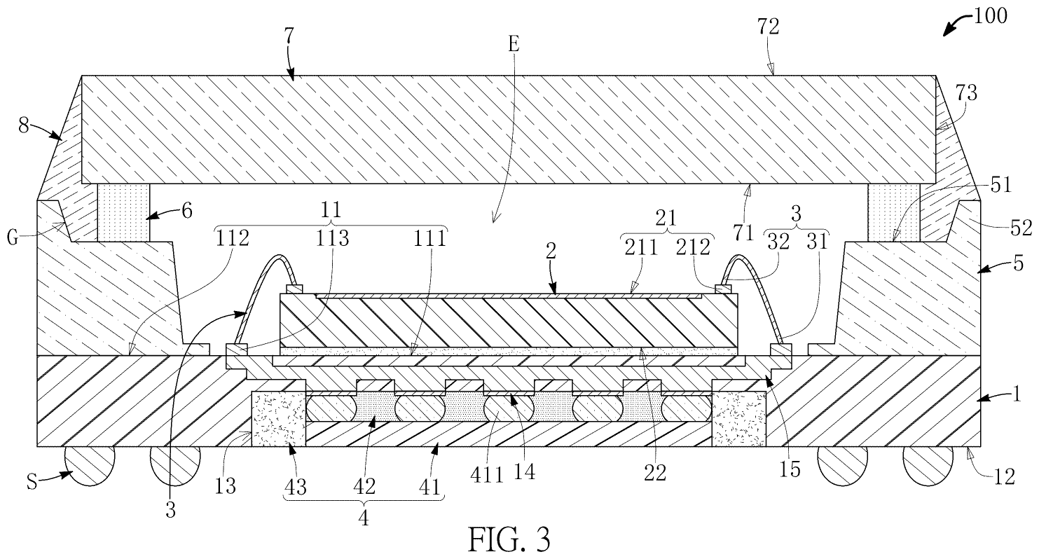

Referring to FIG. 1 to FIG. 4, a first embodiment of the present disclosure is provided. As shown in FIG. 1 to FIG. 3, the present embodiment provides a sensor package structure 100 that can be a contact image sensor (CIS) package structure. In other words, any package structure not encapsulating a sensor chip therein has a structural design different from that of the sensor package structure 100 of the present embodiment.

The sensor package structure 100 in the present embodiment includes a substrate 1, a sensor chip 2 disposed on one side of the substrate 1, a plurality of metal wires 3 connected to the sensor chip 2 and the substrate 1, an embedded module 4 embedded in another side of the substrate 1, a ring-shaped frame 5 being formed on the substrate 1 and surrounding the sensor chip 2 and the metal wires 3, a ring-shaped supporting layer 6 formed on the ring-shaped frame 5, a light-permeable sheet 7 fixed to the ring-shaped supporting layer 6, and a solidified liquid compound 8 that covers lateral sides of the ring-shaped supporting layer 6 and the light-permeable sheet 7.

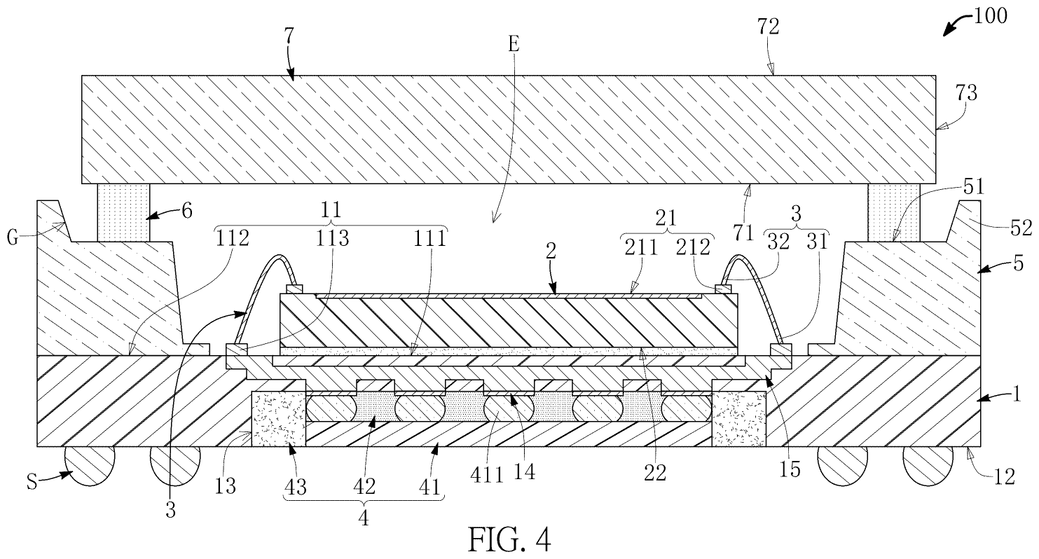

The sensor package structure 100 in the present embodiment includes the above components, but can be adjusted or changed according to design requirements. For example, as shown in FIG. 4, the sensor package structure 100 can be provided without the solidified liquid compound 8 according to practical requirements. The structure and connection relationship of each component of the sensor package structure 100 are recited in the following description.

The substrate 1 of the present embodiment has a square shape or a rectangular shape, but the present disclosure is not limited thereto. The substrate 1 has an upper surface 11 and a lower surface 12 that is opposite to the upper surface 11. The upper surface 11 of the substrate 1 includes a chip-bonding region 111 arranged approximately on a center portion thereof and a carrying region 112 that surrounds the chip-bonding region 111. The substrate 1 includes a plurality of first bonding pads 113 that are arranged on the carrying region 112. The first bonding pads 113 in the present embodiment are in an annular arrangement, but the present disclosure is not limited thereto. For example, in other embodiments of the present disclosure not shown in the drawings, the first bonding pads 113 can be arranged in two rows respectively at two opposite sides of the chip-bonding region 111.

Moreover, the substrate 1 has an accommodating slot 13 that is recessed from the lower surface 12 toward the chip-bonding region 111, and the accommodating slot 13 is preferably provided with the following features: outer edges of the first bonding pads 113 jointly define a formation boundary B, and a projection area defined by orthogonally projecting the accommodating slot 13 onto the upper surface 11 is located inside of the formation boundary B, but the present disclosure is not limited thereto.

The substrate 1 includes a plurality of second bonding pads 14 arranged on a bottom of the accommodating slot 13 and a fan-out circuit 15 that extends from the second bonding pads 14 to the first bonding pads 113. Moreover, a quantity of the first bonding pads 113 preferably corresponds to (e.g., is equal to) a quantity of the second bonding pads 14.

In addition, the substrate 1 can be further provided with a plurality of solder balls S that are disposed on the lower surface 12 thereof and that are located outside of the accommodating space 13. Accordingly, the substrate 1 can be soldered onto an electronic component (not shown in the drawings) through the solder balls S, thereby electrically connecting the sensor package structure 100 to the electronic component.

The sensor chip 2 in the present embodiment is a contact image sensor (CIS), but the present disclosure is not limited thereto. The sensor chip 2 is fixed onto the chip-bonding region 111 of the substrate 1 through a bottom surface 22 thereof. In other words, the sensor chip 2 is arranged to be surrounded on the inside of the first bonding pads 113. It should be noted that the sensor package structure 100 in the present embodiment includes an adhesive disposed on the chip-bonding region 111, and the sensor chip 2 is fixed onto the chip-bonding region 111 through the adhesive, but the present disclosure is not limited thereto.

Furthermore, a top surface 21 of the sensor chip 2 has a sensing region 211 and a plurality of connection pads 212 that are arranged outside of the sensing region 211. The number and positions of the connection pads 212 of the sensor chip 2 in the present embodiment correspond to those of the first bonding pads 113 of the substrate 1. In other words, the connection pads 212 are in an annular arrangement, and a quantity of the connection pads 212 is equal to a quantity of the first bonding pads 113.

Each of the metal wires 3 has a first end portion 31 and a second end portion 32 that is opposite to the first end portion 31. The first end portions 31 of the metal wires 3 are respectively connected to the first bonding pads 113, and the second end portions 32 of the metal wires 3 are respectively connected to the connection pads 212, so that the substrate 1 can be electrically coupled to the sensor chip 2 through the metal wires 3. Any one of the metal wires 3 can be formed in a normal bond manner or a reserve bond manner according to design requirements, but the present disclosure is not limited thereto.

The embedded module 4 is arranged in the accommodating slot 13 and includes a processor 41, an underfill layer 42, and an inner encapsulant 43. The processor 41 in the present embodiment is an image signal processor (ISP), and a size of the processor 41 is preferably smaller than that of the sensor chip 2. In other words, the embedded module 4 in the present embodiment excludes any electronic chip other than the processor 41.

Specifically, the processor 41 is disposed in the accommodating slot 13 and does not protrude from the lower surface 12, and the processor 41 is preferably located directly under the sensor chip 2. Moreover, the processor 41 is connected to the second bonding pads 14 through solders 411, and the processor 41 is electrically coupled to the sensor chip 2 through the substrate 1 and the metal wires 3.

The underfill layer 42 is arranged between the processor 41 and the bottom of the accommodating slot 13, and the solders 411 and the second bonding pads 14 are embedded in the underfill layer 42. Moreover, the inner encapsulant 43 is filled fully in the accommodating slot 13, and the processor 41 and the underfill layer 42 are embedded in the inner encapsulant 43.

Specifically, the inner encapsulant 43 is preferably ring-shaped and surrounds the processor 41 and the underfill layer 42, an outer side (or a bottom side) of the inner encapsulant 43 is coplanar with the lower surface 12 of the substrate 1, and an outer side (or a bottom side) of the processor 41 is coplanar with the lower surface 12 or can be covered by the inner encapsulant 43 (not shown in the drawings). In addition, a coefficient of thermal expansion (CTE) of the inner encapsulant 43 is preferably between a CTE of the substrate 1 and a CTE of the processor 41, thereby preventing the processor 41 from being damaged due to heat expansion and contraction, but the present disclosure is not limited thereto.

In summary, the sensor package structure 100 of the present embodiment is provided with the structural cooperation of the substrate 1 and the embedded module 4, so that signal transmission paths between the sensor chip 2 and the processor 41 can be significantly shortened to increase overall performance, and the sensor package structure 100 can be effectively miniaturized to facilitate future development and application.

The ring-shaped frame 5 is formed on the carrying region 112 of the upper surface 11 of the substrate 1 and surrounds the sensor chip 2 and the metal wires 3. In the present embodiment, the ring-shaped frame 5 has a stepped surface 51 being ring-shaped and a stopping portion 52 that is ring-shaped and that extends from (a peripheral portion of) the stepped surface 51.

The ring-shaped supporting layer 6 is formed on the stepped surface 51 of the ring-shaped frame 5, and the stopping portion 52 is spaced apart from and surrounds the ring-shaped supporting layer 6, such that the ring-shaped supporting layer 6, the stepped surface 51, and the stopping portion 52 jointly define a ring-shaped groove G. Moreover, a top point of each of the metal wires 3 is lower than the stepped surface 51 with respect to the upper surface 11, and the stopping portion 52 is lower than the ring-shaped supporting layer 6 with respect to the stepped surface 51, but the present disclosure is not limited thereto.

Furthermore, the light-permeable sheet 7 in the present embodiment is a transparent and flat glass board, but the present disclosure is not limited thereto. The light-permeable sheet 7 has an inner surface 71 fixed to the ring-shaped supporting layer 6, an outer surface 72 opposite to the inner surface 71, and a surrounding lateral surface 73 that is connected to the inner surface 71 and the outer surface 72.

Specifically, the inner surface 71 of the light-permeable sheet 7 is fixed to a top end of the ring-shaped supporting layer 6 to enable the light-permeable sheet 7, the ring-shaped supporting layer 6, the ring-shaped frame 5, and the upper surface 11 of the substrate 1 to jointly define an enclosed space E, and the sensor chip 2 and the metal wires 3 are located in the enclosed space E.

In addition, the solidified liquid compound 8 is formed on the ring-shaped frame 5 and surrounds the ring-shaped supporting layer 6. In other words, the ring-shaped groove G in the present embodiment is fully filled with the solidified liquid compound 8, and the solidified liquid compound 8 covers the surrounding lateral surface 73 of the light-permeable sheet 7. The outer surface 72 of the light-permeable sheet 7 in the present embodiment is not covered by the solidified liquid compound 8, but the present disclosure is not limited thereto. For example, in other embodiments of the present disclosure not shown in the drawings, the solidified liquid compound 8 can cover a part (e.g., a peripheral part) of the outer surface 72 of the light-permeable sheet 7.

In should be noted that the ring-shaped frame 5, the ring-shaped supporting layer 6, the light-permeable sheet 7, and the solidified liquid compound 8 in the present embodiment are sequentially provided and disposed one by one, and are not pre-formed in a one-piece structure.

### Second Embodiment

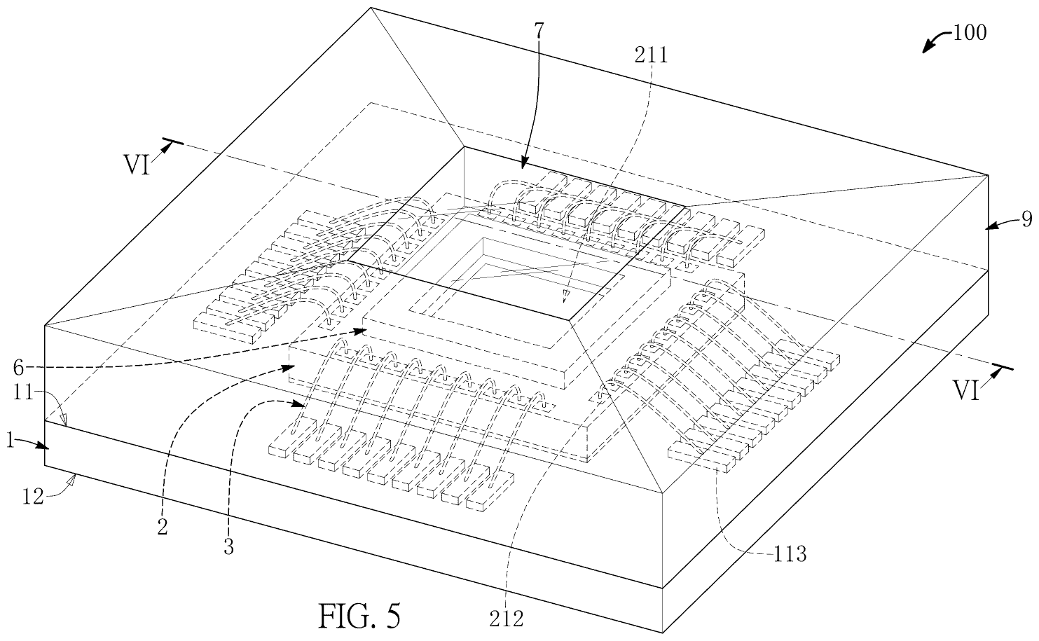

Referring to FIG. 5 to FIG. 7, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the sensor package structure 100 includes a substrate 1, a sensor chip 2 disposed on one side of the substrate 1, a plurality of metal wires 3 connected to the sensor chip 2 and the substrate 1, an embedded module 4 embedded in another side of the substrate 1, a ring-shaped supporting layer 6 formed on the sensor chip 2, a light-permeable sheet 7 fixed to the ring-shaped supporting layer 6, and an outer encapsulant 9 that is formed on the substrate 1.

The substrate 1, the sensor chip 2, the metal wires 3, and the embedded module 4 of the present embodiment are substantially identical to those of the first embodiment, and descriptions of the substrate 1, the sensor chip 2, the metal wires 3, and the embedded module 4 in the present embodiment will be omitted herein for the sake of brevity. Moreover, the ring-shaped supporting layer 6, the light-permeable sheet 7, and the outer encapsulant 9 in the present embodiment are sequentially provided and disposed one by one, and are not pre-formed in a one-piece structure.

In the present embodiment, the ring-shaped supporting layer 6 is formed on the top surface 21 of the sensor 2 and surrounds the sensing region 211. Moreover, the light-permeable sheet 7 provided by the present embodiment is substantially identical to that of the first embodiment, and the light-permeable sheet 7 is fixed to the top end of the ring-shaped supporting layer 6 to enable the light-permeable sheet 7, the ring-shaped supporting layer 6, and the top surface 21 of the sensor 2 to jointly define an enclosed space E, and the sensing region 211 is located in the enclosed space E.

The outer encapsulant 9 is formed on the carrying region 112 of the substrate 1, and the first bonding pads 113, at least part of each of the metal wires 3, the sensor chip 2, the ring-shaped supporting layer 6, and the light-permeable sheet 7 are embedded in the outer encapsulant 9. Moreover, the outer surface 72 of the light-permeable sheet 7 is at least partially exposed from the outer encapsulant 9.

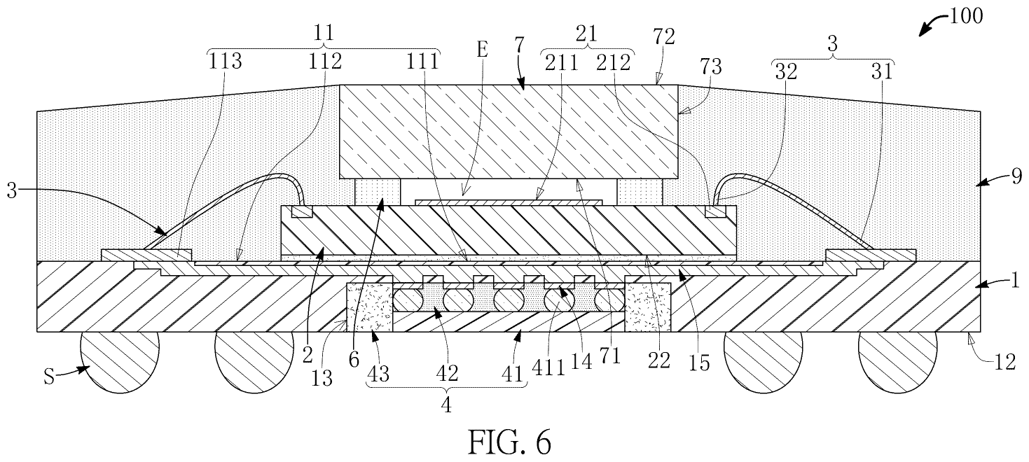

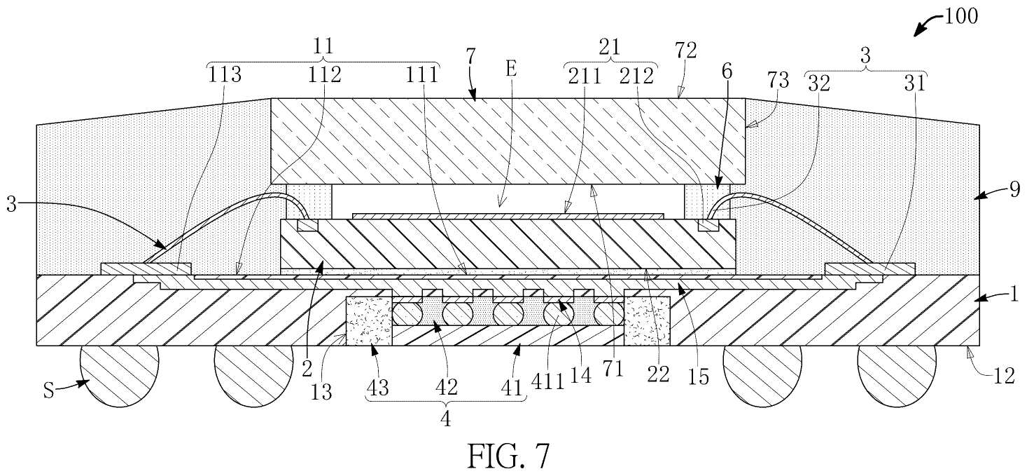

In addition, as shown in FIG. 6, the connection pads 212 can be arranged outside of the ring-shaped supporting layer 6, and the connection pads 212 and the metal wires 3 are entirely embedded in the outer encapsulant 9. Or, as shown in FIG. 7, each of the connection pads 212 and the second end portion 32 of a corresponding one of the metal wires 3 are embedded in the ring-shaped supporting layer 6, and the first end portion 31 of each of the metal wires 3 is embedded in the outer encapsulant 9.

### Third Embodiment

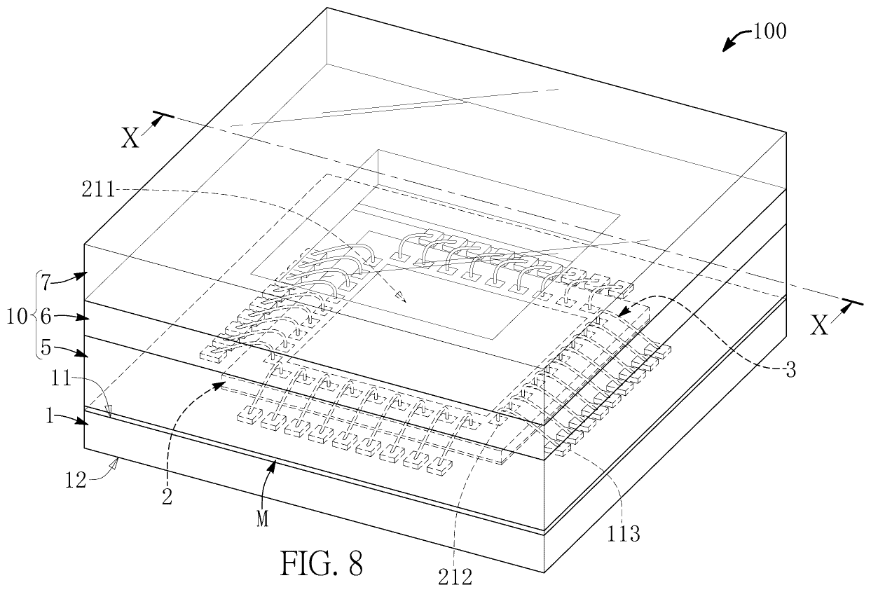

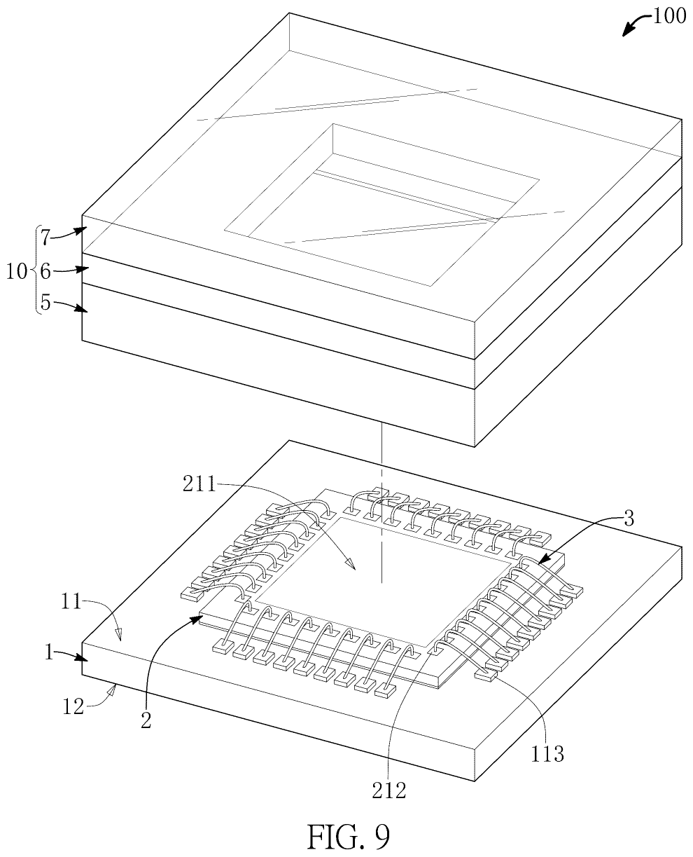

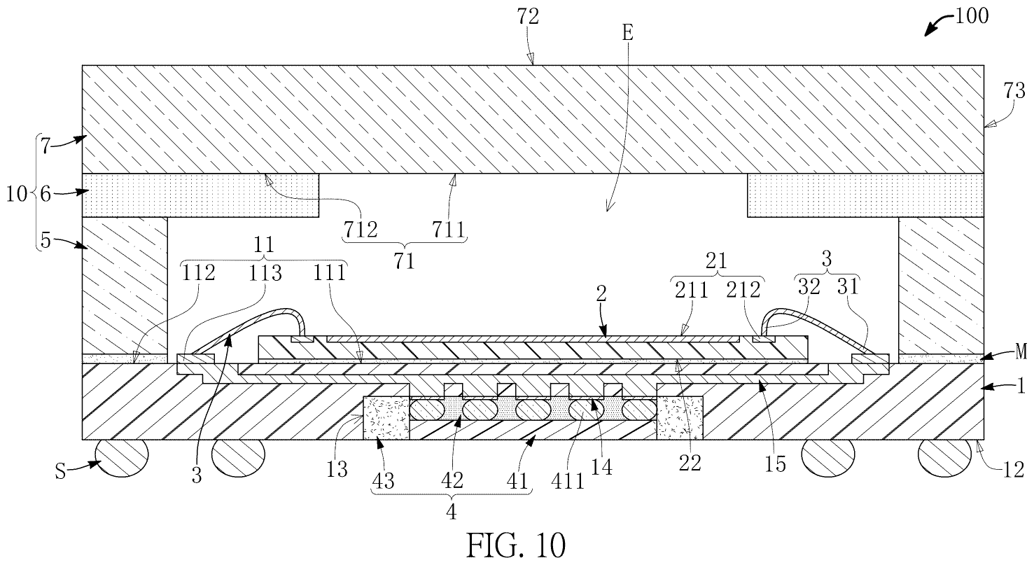

Referring to FIG. 8 to FIG. 10, a third embodiment of the present disclosure, which is similar to the first embodiment of the present disclosure, is provided. For the sake of brevity, descriptions of the same components (e.g., the substrate 1, the sensor chip 2, the metal wires 3, and the embedded module 4) in the first and third embodiments of the present disclosure will be omitted herein, and the following description only discloses different features between the first and third embodiments.

In the present embodiment, the sensor package structure 100 includes a substrate 1, a sensor chip 2 disposed on one side of the substrate 1, a plurality of metal wires 3 connected to the sensor chip 2 and the substrate 1, an embedded module 4 embedded in another side of the substrate 1, and a light-permeable cover 10 that is assembled to the substrate 1.

The substrate 1, the sensor chip 2, the metal wires 3, and the embedded module 4 of the present embodiment are substantially identical to those of the first embodiment, and descriptions of the substrate 1, the sensor chip 2, the metal wires 3, and the embedded module 4 in the present embodiment will be omitted herein for the sake of brevity. Moreover, the light-permeable cover 10 in the present embodiment is pre-formed in a one-piece structure and is used to be assembled onto the carrying region 112 of the substrate 1.

In the present embodiment, the light-permeable cover 10 and the upper surface 11 of the substrate 1 jointly define an enclosed space E, and the sensor chip 2 and the metal wires 3 are located in the enclosed space E. Specifically, the light-permeable cover 10 includes a light-permeable sheet 7, a ring-shaped supporting layer 6 formed on the light-permeable sheet 7, and a ring-shaped frame 5 that is formed on the ring-shaped supporting layer 6.

Specifically, the light-permeable sheet 7 provided by the present embodiment is substantially identical to that of the first embodiment, and the inner surface 71 of the light-permeable sheet 7 has a light-permeable region 711 facing toward the sensing region 211 and a formation region 712 that surrounds the light-permeable region 711. In other words, a projection area defined by orthogonally projecting the light-permeable region 711 onto the top surface 21 of the sensor chip 2 is preferably overlapped with an entirety of the sensing region 211.

Moreover, the ring-shaped supporting layer 6 is formed on the formation region 712, and the ring-shaped supporting layer 6 can be a light shielding layer or a light absorption layer according to practical requirements. The metal wires 3, the first bonding pads 113, and the connection pads 212 are preferably located in a projection space that is defined by orthogonally projecting the ring-shaped supporting layer 6 toward the substrate 1, thereby preventing a sensing result of the sensing region 211 from being affected due to light reflected by the metal wires 3, the first bonding pads 113, and the connection pads 212.

In addition, the ring-shaped frame 5 is formed on (a peripheral part of) the ring-shaped supporting layer 6, and the light-permeable cover 10 is adhered onto the carrying region 112 of the substrate 1 through the ring-shaped frame 5. In other words, the ring-shaped frame 5 of the light-permeable cover 10 and the carrying region 112 of the substrate 1 are adhered to each other through an adhesive layer M.

### Beneficial Effects of the Embodiments

In conclusion, the sensor package structure of the present disclosure is provided with the structural cooperation of the substrate and the embedded module, so that signal transmission paths between the sensor chip and the processor can be significantly shortened to increase overall performance, and the sensor package structure can be effectively miniaturized to facilitate future development and application.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensor package structure, comprising:
a substrate including:
an upper surface having a chip-bonding region and a carrying region that surrounds the chip-bonding region; and
a lower surface being opposite to the upper surface, wherein the substrate has an accommodating slot that is recessed from the lower surface toward the chip-bonding region;
wherein the substrate includes a plurality of first bonding pads arranged on the carrying region, a plurality of second bonding pads arranged on a bottom of the accommodating slot, and a fan-out circuit that extends from the second bonding pads to the first bonding pads;
a sensor chip disposed on the chip-bonding region, wherein a top surface of the sensor chip has a sensing region and a plurality of connection pads that are arranged outside of the sensing region;
a plurality of metal wires each having a first end portion and a second end portion, wherein the first end portions of the metal wires are respectively connected to the first bonding pads, and the second end portions of the metal wires are respectively connected to the connection pads;
an embedded module arranged in the accommodating slot and including:
a processor disposed in the accommodating slot and not protruding from the lower surface, wherein the processor is connected to the second bonding pads through solders, and the processor is electrically coupled to the sensor chip through the substrate and the metal wires;
an underfill layer arranged between the processor and the bottom of the accommodating slot, wherein the solders and the second bonding pads are embedded in the underfill layer; and
an inner encapsulant filled fully in the accommodating slot, wherein the processor and the underfill layer are embedded in the inner encapsulant, and an outer side of the inner encapsulant is coplanar with the lower surface of the substrate;
a ring-shaped frame being formed on the carrying region of the upper surface and surrounding the sensor chip and the metal wires;
a ring-shaped supporting layer formed on the ring-shaped frame; and
a light-permeable sheet that is fixed to the ring-shaped supporting layer to enable the light-permeable sheet, the ring-shaped supporting layer, the ring-shaped frame, and the upper surface of the substrate to jointly define an enclosed space, wherein the sensor chip and the metal wires are located in the enclosed space.

2. The sensor package structure according to claim 1, wherein the light-permeable sheet has an inner surface fixed to the ring-shaped supporting layer, an outer surface opposite to the inner surface, and a surrounding lateral surface that is connected to the inner surface and the outer surface, and wherein the sensor package structure further includes a solidified liquid compound formed on the ring-shaped frame and surrounding the ring-shaped supporting layer, and the solidified liquid compound covers the surrounding lateral surface of the light-permeable sheet.

3. The sensor package structure according to claim 2, wherein the ring-shaped frame has a stepped surface and a stopping portion that extends from the stepped surface, and wherein the ring-shaped supporting layer is formed on the stepped surface, such that the ring-shaped supporting layer, the stepped surface, and the stopping portion jointly define a ring-shaped groove that is fully filled with the solidified liquid compound.

4. The sensor package structure according to claim 3, wherein a top point of each of the metal wires is lower than the stepped surface with respect to the upper surface, and the stopping portion is lower than the ring-shaped supporting layer with respect to the stepped surface.

5. The sensor package structure according to claim 1, wherein outer edges of the first bonding pads jointly define a formation boundary, and a projection area defined by orthogonally projecting the accommodating slot onto the upper surface is located inside of the formation boundary.

6. The sensor package structure according to claim 1, wherein a size of the processor is smaller than that of the sensor chip, and the processor is located directly under the sensor chip.

7. A sensor package structure, comprising:
a substrate including:
an upper surface having a chip-bonding region and a carrying region that surrounds the chip-bonding region; and
a lower surface being opposite to the upper surface, wherein the substrate has an accommodating slot that is recessed from the lower surface toward the chip-bonding region;
wherein the substrate includes a plurality of first bonding pads arranged on the carrying region, a plurality of second bonding pads arranged on a bottom of the accommodating slot, and a fan-out circuit that extends from the second bonding pads to the first bonding pads;
a sensor chip disposed on the chip-bonding region, wherein a top surface of the sensor chip has a sensing region and a plurality of connection pads that are arranged outside of the sensing region;
a plurality of metal wires each having a first end portion and a second end portion, wherein the first end portions of the metal wires are respectively connected to the first bonding pads, and the second end portions of the metal wires are respectively connected to the connection pads;
an embedded module arranged in the accommodating slot and including:
a processor disposed in the accommodating slot and not protruding from the lower surface, wherein the processor is connected to the second bonding pads through solders, and the processor is electrically coupled to the sensor chip through the substrate and the metal wires;
an underfill layer arranged between the processor and the bottom of the accommodating slot, wherein the solders and the second bonding pads are embedded in the underfill layer; and
an inner encapsulant filled fully in the accommodating slot, wherein the processor and the underfill layer are embedded in the inner encapsulant, and an outer side of the inner encapsulant is coplanar with the lower surface of the substrate;
a ring-shaped supporting layer being formed on the top surface of the sensor and surrounding the sensing region;
a light-permeable sheet that is fixed to the ring-shaped supporting layer to enable the light-permeable sheet, the ring-shaped supporting layer, and the top surface of the sensor to jointly define an enclosed space, wherein the sensing region is located in the enclosed space; and
an outer encapsulant formed on the carrying region of the substrate, wherein the first bonding pads, at least part of each of the metal wires, the sensor chip, the ring-shaped supporting layer, and the light-permeable sheet are embedded in the outer encapsulant, and wherein an outer surface of the light-permeable sheet is at least partially exposed from the outer encapsulant.

8. The sensor package structure according to claim 7, wherein the connection pads are arranged outside of the ring-shaped supporting layer, and the connection pads and the metal wires are entirely embedded in the outer encapsulant.

9. The sensor package structure according to claim 7, wherein each of the connection pads and the second end portion of a corresponding one of the metal wires are embedded in the ring-shaped supporting layer, and the first end portion of each of the metal wires is embedded in the outer encapsulant.

10. The sensor package structure according to claim 7, wherein outer edges of the first bonding pads jointly define a formation boundary, and a projection area defined by orthogonally projecting the accommodating slot onto the upper surface is located inside of the formation boundary.

11. The sensor package structure according to claim 7, wherein a size of the processor is smaller than that of the sensor chip, and the processor is located directly under the sensor chip.

12. A sensor package structure, comprising:
a substrate including:
an upper surface having a chip-bonding region and a carrying region that surrounds the chip-bonding region; and
a lower surface being opposite to the upper surface, wherein the substrate has an accommodating slot that is recessed from the lower surface toward the chip-bonding region;
wherein the substrate includes a plurality of first bonding pads arranged on the carrying region, a plurality of second bonding pads arranged on a bottom of the accommodating slot, and a fan-out circuit that extends from the second bonding pads to the first bonding pads;
a sensor chip disposed on the chip-bonding region, wherein a top surface of the sensor chip has a sensing region and a plurality of connection pads that are arranged outside of the sensing region;
a plurality of metal wires each having a first end portion and a second end portion, wherein the first end portions of the metal wires are respectively connected to the first bonding pads, and the second end portions of the metal wires are respectively connected to the connection pads;
an embedded module arranged in the accommodating slot and including:
a processor disposed in the accommodating slot and not protruding from the lower surface, wherein the processor is connected to the second bonding pads through solders, and the processor is electrically coupled to the sensor chip through the substrate and the metal wires;
an underfill layer arranged between the processor and the bottom of the accommodating slot, wherein the solders and the second bonding pads are embedded in the underfill layer; and
an inner encapsulant filled fully in the accommodating slot, wherein the processor and the underfill layer are embedded in the inner encapsulant, and an outer side of the inner encapsulant is coplanar with the lower surface of the substrate; and
a light-permeable cover assembled to the carrying region, wherein the light-permeable cover and the upper surface of the substrate jointly define an enclosed space, and the sensor chip and the metal wires are located in the enclosed space.

13. The sensor package structure according to claim 12, wherein the light-permeable cover includes:
a light-permeable sheet having an inner surface, wherein the inner surface has a light-permeable region facing the sensing region and a formation region that surrounds the light-permeable region;
a ring-shaped supporting layer formed on the formation region; and
a ring-shaped frame formed on the ring-shaped supporting layer, wherein the light-permeable cover is a one-piece structure and is adhered onto the carrying region of the substrate through the ring-shaped frame.

14. The sensor package structure according to claim 13, wherein outer edges of the first bonding pads jointly define a formation boundary, and a projection area defined by orthogonally projecting the accommodating slot onto the upper surface is located inside of the formation boundary.

15. The sensor package structure according to claim 13, wherein a size of the processor is smaller than that of the sensor chip, and the processor is located directly under the sensor chip.
